(19) United States
(12) Patent Application Publication
(10) Pub. No.: US 2026/0322262 A1
(43) Pub. Date: Oct. 15, 2026

(54) AUTOMATIC POWER CONTROL CIRCUIT

(71) Applicant: Grace Connection Microelectronics Limited, ZHUBEI CITY (TW)

(72) Inventors: PEI-WEI CHEN, ZHUBEI CITY (TW); HSIEN-KU CHEN, ZHUBEI CITY (TW)

(73) Assignee: Grace Connection Microelectronics Limited, ZHUBEI CITY (TW)

(21) Appl. No.: 19/364,933

(22) Filed: Oct. 21, 2025

(30) Foreign Application Priority Data
Nov. 5, 2024 (TW) 113142337

(51) Int. Cl. H02M 3/155; H03M 1/66

(52) U.S. Cl. CPC H02M 3/155; H03M 1/66

(57) ABSTRACT

An automatic power control circuit for an optical communication chip, which is coupled to a digital control unit and a DC-DC converter. The automatic power control circuit includes: a digital-to-analog converter (DAC) coupled to the digital control unit, wherein the digital-to-analog converter receives a digital code from the digital control unit to generate a DAC output voltage; an output buffer circuit, coupled to the digital-to-analog converter and the DC-DC converter, the output buffer circuit providing an internal node voltage; and an analog-to-digital converter (ADC), coupled to the output buffer circuit and the digital control unit, wherein the analog-to-digital converter controls a supply voltage of the DC-DC converter through the digital analog converter, to ensure that a voltage difference between the supply voltage and the internal node voltage is maintained within a normal operating range.

### CROSS REFERENCE

The present invention claims priority to TW113142337 filed on Nov. 5, 2024.

### BACKGROUND OF THE INVENTION

### Field of Invention

The present invention relates to an automatic power control circuit.

### Description of Related Art

The optical communication chips currently play a critical role in modern communications. The following are some key applications:

High-Efficiency data transmission: the optical communication chips utilize optical signals for data transmission, which offers wider bandwidth and higher speed than traditional electrical signals. This enables the rapid transmission of large volumes of data within an extremely short time period, to make them suitable for high-speed internet, data centers, and large-scale computing applications.

Low Latency and high Stability: optical signal transmission has low latency, and is not affected by electromagnetic interference, which ensures stable and reliable data communication. This is particularly important for applications requiring high-precision and real-time performance, such as financial transactions and telemedicine.

Low-power consumption: the optical communication chips consume relatively low power due to the high transmission efficiency of optical signals and their lower heat generation. It helps save a lot of energy and reduce operational costs in large-scale facilities such as data centers that require long-term operation.

Long-distance communication: fiber optic communication allows data transmission over extremely long distances with low signal attenuation. The optical communication chips are widely used in transcontinental and international communication networks to achieve global communication connectivity.

Telecom infrastructure: modern telecommunication networks mainly rely on the optical communication chips to play a key role in base stations, switches, and routers, supporting high-speed internet, 5G networks, and other telecommunication services.

Data center interconnection: in large data centers, high-speed connectivity is required between individual servers and storage devices. The optical communication chips provide wide bandwidth and low latency connections to improve the operational efficiency of the data centers.

Quantum communication: the optical communication chips are also key components in quantum communication technology. Quantum communication employs the quantum states of photons in transmission, to achieve ultra-secure communication.

Therefore, effectively reduce the energy consumption of the optical communication chips is one key focus of the industry's efforts

### SUMMARY OF THE INVENTION

In view of the aforementioned technical needs, according to one perspective of the present invention, an automatic power control circuit of an optical communication chip is provided. The automatic power control circuit is coupled to a digital control unit and a DC-DC converter. The automatic power control circuit includes: a digital-to-analog converter (DAC) coupled to the digital control unit, wherein the digital-to-analog converter receives a digital code from the digital control unit to generate a DAC output voltage; an output buffer circuit, coupled to the digital-to-analog converter and the DC-DC converter, the output buffer circuit providing an internal node voltage; and an analog-to-digital converter (ADC), coupled to the output buffer circuit and the digital control unit, wherein the analog-to-digital converter controls a supply voltage outputted by the DC-DC converter through the digital analog converter, to ensure that a voltage difference between the supply voltage and the internal node voltage is maintained within a normal operating range.

The objectives, technical details, features, and benefits of the present invention can be better understood with regard to the detailed description of the embodiments below, with reference to the associated drawings.

### BRIEF DESCRIPTION OF THE DRAWINGS

FIGS. 1A and 1B show the schematic circuit diagram of an automatic power control circuit according to one embodiment of the present invention.

FIG. 2 shows the schematic circuit diagram of an automatic power control circuit according to one embodiment of the present invention.

FIG. 3A shows the schematic circuit diagram of an automatic power control circuit according to one embodiment of the present invention.

FIG. 3B shows the schematic circuit diagram of an automatic power control circuit according to one embodiment of the present invention.

FIG. 4 shows the schematic circuit diagram of an automatic power control circuit according to one embodiment of the present invention.

FIG. 5 shows the schematic circuit diagram of the automatic power control circuit according to one embodiment of the present invention.

### DESCRIPTION OF THE PREFERRED EMBODIMENTS

The technical wordings/terms in this specification are based on customary understanding of the art. Regarding the wording described or defined in this specification, the interpretations of these wordings/terms are preferentially based on the description or the definition in this specification. Each embodiment of the present invention includes at least one technical feature. To the extent possible, a person having ordinary knowledge in the art may, as needed, select, combine, or modify some or all of the technical features in any one of the embodiments, within the spirit and scope of the present invention.

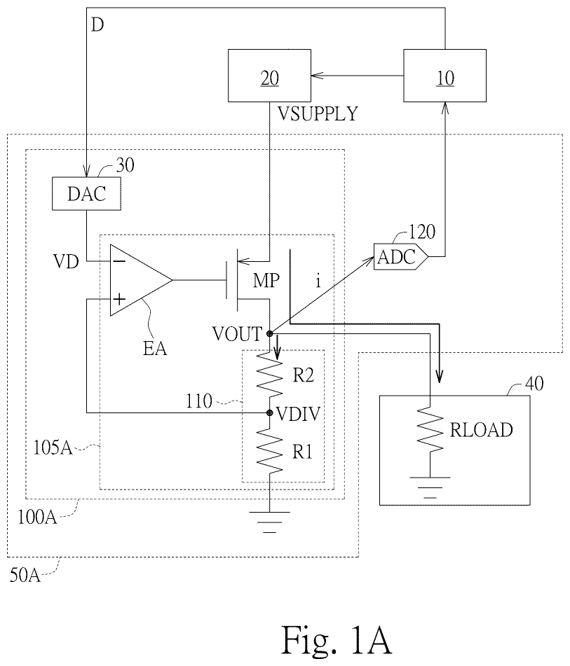

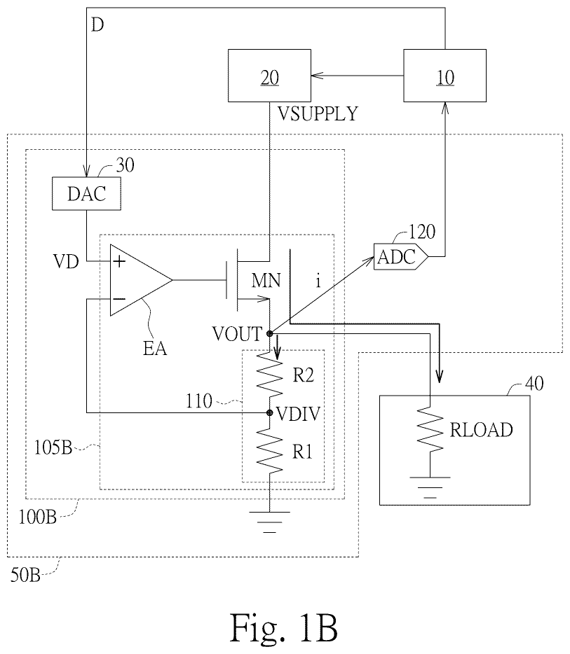

Please refer to FIGS. 1A and 1B, wherein a schematic circuit diagram of an automatic power control circuit according to one embodiment of the present invention is shown. The automatic power control circuit 50A of this embodiment may, for example, be applied to an optical communication chip, but can be not limited to this. A digital control unit 10, a DC-DC converter 20, and an electrical load 40 are coupled to the automatic power control circuit 50A. The optical communication chip (not shown) includes: the digital control unit 10, the DC-DC converter 20, the electrical load 40, and the automatic power control circuit 50A. The automatic power control circuit 50A includes a voltage mode digital-to-analog converter (VDAC) 100A and an analog-to-digital converter (ADC) 120, wherein the voltage mode analog-to-digital converter 120 is an optional component. The voltage mode digital-to-analog converter (VDAC) 100A includes: a digital-to-analog converter (DAC) 30, and an output buffer circuit 105A.

The digital control unit 10 is coupled to the DC-DC converter 20. The digital control unit 10 generates a digital code D to a digital-to-analog converter 30, based on an internal node voltage VOUT of the voltage mode digital-to-analog converter 100A or 100B, in order to control a DAC output voltage VD generated by the digital-to-analog converter 30. That is, in FIGS. 1A and 1B, the internal node voltage VOUT of the voltage mode digital-to-analog converter 100A or 100B is detected to control the digital-to-analog converter 30, to generate the DAC output voltage VD.

The DC-DC converter 20 generates a supply voltage VSUPPLY and supply an electric current i to the voltage mode digital-to-analog converter 100A or 100B.

The digital-to-analog converter 30 receives the digital code generated by the digital control unit 10, to generate the DAC output voltage VD.

The electrical load 40 includes, for example, a load resistor RLOAD, but can be not limited to this. One terminal of the load resistor RLOAD is coupled to the internal node voltage VOUT. The load resistor RLOAD may be, for example, a silicon photonic circuit to control the wavelength or the phase, but can be not limited to this.

In one embodiment, the output buffer circuit 105A includes: a transistor MP, an error amplifier EA, and a voltage divider circuit 110.

The transistor MP includes: a first terminal (e.g., a source terminal), which receives a supply voltage VSUPPLY generated by the DC-DC converter 20; a second terminal (e.g., a drain terminal) coupled to the voltage divider circuit 110 and the electrical load 40; and, a control terminal (e.g., a gate terminal) which receives an output signal from the error amplifier EA.

The error amplifier EA includes: a first terminal (e.g., a positive input terminal) receiving a divided voltage VDIV from the voltage divider circuit 110; a second terminal (e.g., a negative input terminal) receiving the DAC output voltage VD from the digital-to-analog converter 30; and, an output terminal coupled to the control terminal of the transistor MP.

The voltage divider circuit 110 divides the internal node voltage VOUT to generate the divided voltage VDIV, which is feedbacked to the first terminal of the error amplifier EA. The voltage divider circuit 110 includes resistors R1 and R2. The resistor R1 includes: a first terminal coupled to a second terminal of the resistor R2, and a second terminal coupled to grounding. The resistor R2 includes: a first terminal coupled to the second terminal of transistor MP, and a second terminal coupled to the first terminal of the resistor R1.

In one embodiment, the analog-to-digital converter 120 converts the internal node voltage VOUT of the output buffer circuit 105A into a digital signal, and transmits the digital signal to the digital control unit 10, which enables the digital control unit 10 generates the digital code D based on the digital signal to the digital-to-analog converter 30.

Being different from the output buffer circuit 105A, the transistor in the output buffer circuit 105B is an N-type transistor MN. The N-type transistor MN includes: a first terminal (e.g., a drain terminal) receiving the supply voltage VSUPPLY generated by the DC-DC converter 20; a second terminal (e.g., a source terminal) coupled to the voltage divider circuit 110 and the electrical load 40; and a control terminal (e.g., a gate terminal) receiving an output signal from an error amplifier EA.

In one embodiment, in the output buffer circuit 105B, the error amplifier EA includes: a first terminal (e.g., a positive input terminal) receiving the DAC output voltage VD generated by the digital-to-analog converter 30; a second terminal (e.g., a negative input terminal) receiving a divided voltage VDIV from the voltage divider circuit 110; and an output terminal coupled to the control terminal of the transistor MN. The transistor MN, the error amplifier EA and the voltage divider circuit 110 form the output buffer circuit 105B.

Generally, the operation details of the automatic power control circuit 50A and 50B can be the same or similar. Therefore, the following describes the operating details of the automatic power control circuit 50A. The operation details of the automatic power control circuit 50B can be understood according to that of the automatic power control circuit 50A, by those who are skilled in the art.

In one embodiment of the present invention, a feedback control is employed for reducing the power consumption of transistor MP (or MN), the details are described and explained below.

Please refer to FIG. 1A or FIG. 1B, the power consumption P of the transistor MP is: P=(VSUPPLY−VOUT)*i=VDS*i, wherein i is the supply current flowing through the transistor MP and the electrical load 40, and VDS is the drain-source voltage difference of the transistor MP.

Generally, the internal node voltage VOUT can be obtained through the DAC output voltage VD. When the voltages at the two terminals of the error amplifier EA are equal, it can be deduced that VOUT=(1+R1/R2)*VD. Therefore, the value of VOUT can be known by the above equation. However, in this embodiment, for more precise control, the internal node voltage VOUT can be detected by the analog-to-digital converter 120; that is, the internal node voltage VOUT can be converted into a digital signal by the analog-to-digital converter 120, and the digital signal will be transmitted to the digital control unit 10.

The DAC output voltage VD is related to the digital code D generated by the digital control unit.10 For illustrative purpose, the digital code D can be described as a 4-bit code for one example, while it is understood that the present invention can be not limited to this. When digital code D is 0000, the DAC output voltage VD is the first voltage value; when the digital code D is 0001, the DAC output voltage VD is at the second voltage value. The rest details related to the digital code can be deduced in the same manner. In addition, through the feedback control of the error amplifier EA, the DAC output voltage VD can be very close to the divided voltage VDIV. When the resistance of the resistor R2 is very low, the internal node voltage VOUT is also very close to the divided voltage VDIV.

Therefore, through the digital signal of the analog-to-digital converter 120, the digital control unit 10 can regulate the DAC output voltage VD of the digital-to-analog converter 30, to ensure the condition VDS=(VSUPPLY−VOUT)≥VDS_MIN, wherein VDS represents the drain-source voltage difference of the transistor MP, and VDS_MIN represents the minimum drain-source voltage difference of the transistor MP. That is to say, as long as that VDS=(VSUPPLY−VOUT)≥VDS_MIN is met, the power consumption of transistor MP can be reduced by minimizing the value of (VSUPPLY−VOUT), thereby reducing the heat dissipation and temperature of transistor MP.

That is, in one embodiment of the present invention, the analog-to-digital converter 120 controls the voltage difference between the supply voltage VSUPPLY and the internal node voltage VOUT, to enable the transistor MP operating within a normal operating range because of the voltage difference maintained at or below a voltage level.

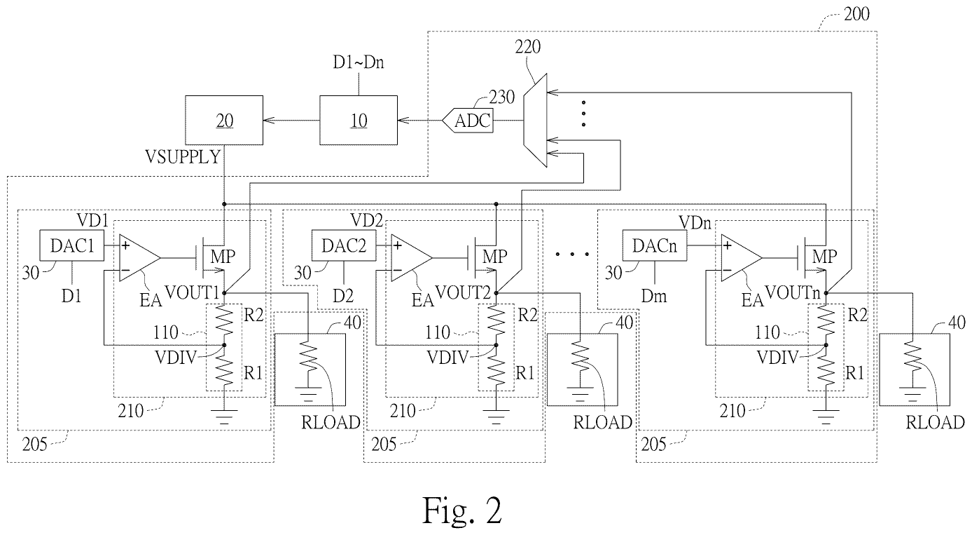

FIG. 2 shows a schematic circuit diagram of the automatic power control circuit according to another embodiment of the present invention. As shown in FIG. 2, the automatic power control circuit 200 includes: a plurality of voltage mode digital-to-analog converters 205, a multiplexer 220, and an analog-to-digital converter (ADC) 230. Each of the voltage mode digital-to-analog converters 205 includes: the digital-to-analog converter 30 and the output buffer circuit 210.

Each of the output buffer circuits 210 includes the transistor MP, the error amplifier EA, and a voltage divider circuit 110. In FIG. 2, the output buffer circuit 210 can be implemented by the output buffer circuit 105A of FIG. 1A. However, in other embodiments of the present invention, the output buffer circuits 210 can be implemented by the output buffer circuit 105B in FIG. 1B, which also falls within the spirit of the present invention.

The multiplexer 220 is coupled to the output buffer circuits 210 of the voltage mode digital-to-analog converters 205.

The analog-to-digital converter 230 is coupled to multiplexer 220.

That is, these voltage mode digital-to-analog converters 205 share the analog-to-digital converter 230 with connection to the analog-to-digital converter 230.

Regarding the operation details of FIG. 2, the multiplexer 220 employs a time-division multiplexing detection technique to select one of the internal node voltages VOUT1-VOUTn of the output buffer circuits 210, to be transmitted to the ADC 230 at various time points. The ADC 230 converts one of the internal node voltages VOUT1-VOUTn, into a digital signal and transmits the digital signal to the digital control unit 10. Based on the digital signal, the digital control unit 10 generates one of the digital codes D1-Dn, to control the digital-to-analog converters 30 for generating the DAC output voltage VD1~VDn.

That is, in FIG. 2, the detection of the internal node voltages VOUT1-VOUTn of the automatic power control circuit 200, can be employed to control the digital-to-analog converter 30 to generate DAC output voltages VD1~VDn.

For example, for reducing the power consumption of the transistor MP and VDAC 30, the control voltage VSUPPLY is controlled under the condition that VDS=(VSUPPLY−VOUT MAX)≥VDS_MIN, wherein VOUT_MAX represents the maximum value of the internal node voltage VOUT1-VOUTn.

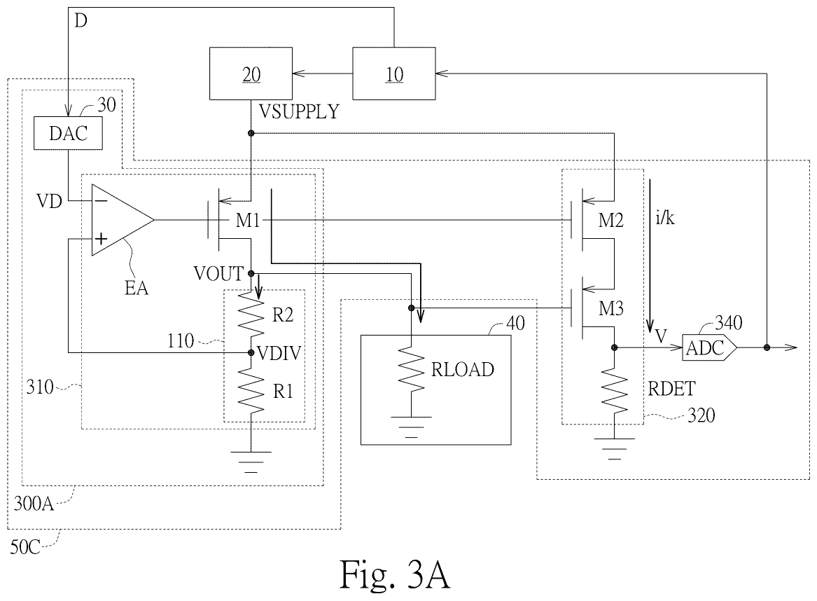

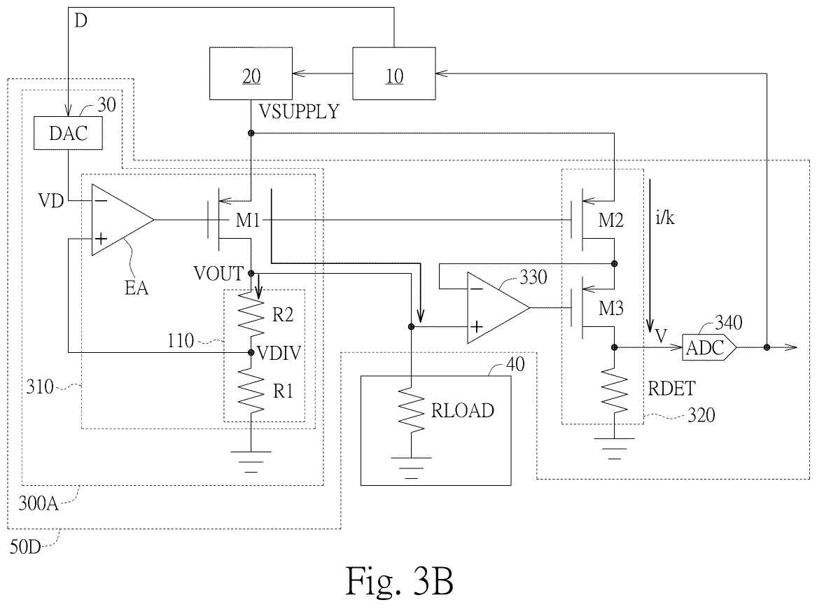

FIG. 3A shows a schematic circuit diagram of the automatic power control circuit according to one embodiment of the present invention. As shown in FIG. 3A, the automatic power control circuit 50C includes: a VDAC 300A, a current mirror circuit 320, an ADC 340. The VDAC 300A includes: DAC 30 and an output buffer circuit 310.

In FIG. 3A, the output buffer circuit 310 can be implemented by the output buffer circuit 105A of FIG. 1A. However, in other embodiments of the present invention, the output buffer circuit 310 is implemented by the output buffer circuit 105B of FIG. 1B, which is also within the spirit of the present invention.

The current mirror circuit 320 can be used to mirror the internal transistor current of the output buffer circuit 310. The current mirror circuit 320 includes transistors M2 and M3, and a detection resistor RDET. The transistor M2 includes a first terminal (e.g., a source terminal), coupled to the DC-DC converter 20 to receive the supply voltage VSUPPLY; a second terminal (e.g., a drain terminal), coupled to the transistor M3; and, a control terminal receiving an output signal from the error amplifier EA. The transistor M3 includes: a first terminal (e.g., a source terminal) coupled to a second terminal of the transistor M2; a second terminal (e.g., a drain terminal) coupled to the detection resistor RDET and the ADC 340; and, a control terminal coupled to the transistor M1. The detection resistor RDET includes a first terminal coupled to the transistor M3 and the ADC 340, and a second terminal coupled to grounding.

The ADC 340 converts the detection voltage of the detection resistor RDET into a digital signal and sends it to the digital control unit 10, which generates the digital code D for the digital-to-analog converter 30 based on the digital signal from the ADC 340, to control the DAC output voltage VD generated by the digital-to-analog converter 30. In FIG. 3A, the transistor current of the automatic power control circuit 50C (i.e., current flowing through the transistor M1, M2 or M3) is detected to control the digital-to-analog converter 30 for generating the DAC output voltage VD.

In one embodiment, a dimension ratio of the transistor M1 to the transistor M2 is k:1. Accordingly, the current value flowing through the current mirror 320 is i/k, so that a detection voltage V across a detection resistance RDET can be expressed as: V=RDET*i/k. Therein, the current i can be derived as: i=V*k/RDET.

In a similar manner, the power consumption P of the transistor M1 is P=(VSUPPLY−VOUT)*i. Therefore, when the digital control unit 10 determines that P exceeds an allowable power limit, the digital control unit 10 adjusts the DAC output voltage VD generated by the digital-to-analog converter 30 to a lower value, to reduce the power consumption P until P falls within the allowable power limit (or less than an upper limit of the allowable power limit). Naturally, this control must still satisfy the condition (VSUPPLY−VOUT)≥VDS_MIN.

FIG. 3B shows a schematic circuit diagram of the automatic power control circuit according to one embodiment of the present invention. As shown in FIG. 3B, the automatic power control circuit 50D includes: a VDAC 300A, a current mirror circuit 320, the ADC 340, and an error amplifier 330.

In FIG. 3B, the output buffer circuit 310 can be implemented by the output buffer circuit 105A of FIG. 1A. However, in other embodiments of the present invention, the output buffer circuit 310 can be implemented by the output buffer circuit 105B of FIG. 1B, which is also within the spirit of the present invention.

The current mirror circuit 320 can be employed to mirror the internal transistor current of the output buffer circuit 310. The current mirror circuit 320 includes: transistors M2 and M3, and a detection resistor RDET. The transistor M2 includes a first terminal (e.g., a source terminal) coupled to the DC-DC converter 20 to receive the supply voltage VSUPPLY; a second terminal (e.g., a drain terminal) coupled to the transistor M3; and, a control terminal receiving an output signal from the error amplifier EA. The transistor M3 includes: a first terminal (e.g., a source terminal) coupled to the second terminal of the transistor M2; a second terminal (e.g., a drain terminal) coupled to a detection resistor RDET and the ADC 340; and, a control terminal receiving the error amplifier 330. The detection resistor RDET includes: a first terminal coupled to the transistor M3 and the ADC 340, and a second terminal coupled to grounding.

The error amplifier 330 includes: a first terminal (e.g., a positive input terminal) coupled to the internal node voltage VOUT; a second terminal (e.g., a negative input) coupled to a coupling point of the transistor M2 and M3 of the current mirror circuit 330; and, an output terminal coupled to the control terminal of the transistor M3 of the current mirror circuit 330. The error amplifier 330 can be used to compare the internal node voltage VOUT with one of the coupled node voltages of the transistor M2 and M3 of the current mirror circuit 330.

The ADC 340 converts the detection voltage of the detection resistor RDET into a digital signal and sends it to the digital control unit 10. The digital control unit 10 generates the digital code D to the digital-to-analog converter 30, based on the digital signal from the ADC 340, to control the digital-to-analog converter 30 for generating the DAC output voltage VD. In FIG. 3B, the DAC output voltage VD is detected. In other words, in FIG. 3B, the transistor current (current flowing through the transistors M1, M2 or M3) of the automatic power control circuit 50D is detected for controlling the output voltage VD generated by digital-to-analog converter 30.

In one embodiment, a dimension ratio of the transistor M1 to the transistor M2 is k:1. Accordingly, the current value flowing through the current mirror 320 is i/k, so that a detection voltage V across a detection resistance RDET can be expressed as: V=RDET*i/k. Therein, the current i can be derived as: i=V*k/RDET.

In a similar manner, the power consumption P of the transistor M1 is P=(VSUPPLY−VOUT)*i. Therefore, when the digital control unit 10 determines that P exceeds the allowable power limit (or, to be higher than the upper limit of the allowable power limit), the digital control unit 10 adjusts the DAC output voltage VD generated by the digital-to-analog converter 30 to a lower value, to reduce the power consumption P until P falls within the allowable power limit (or, less than the upper limit of the allowable power limit). Naturally, this control must still satisfy the condition (VSUPPLY−VOUT)≥VDS_MIN.

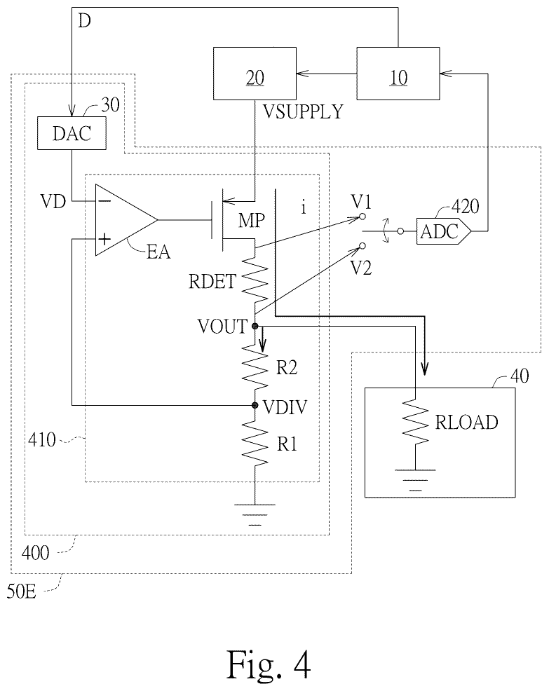

FIG. 4 shows a schematic circuit diagram of the automatic power control circuit according to one embodiment of the present invention. As shown in FIG. 4, the automatic power control circuit 50E of the present invention includes: a VDAC 400, an ADC 420. The VDAC 400 includes a DAC 30, and an output buffer circuit 410. The output buffer circuit 410 includes: the error amplifier EA, the transistor MP, resistors R1, R2, and the detection resistor RDET.

The detection resistor RDET includes a first terminal coupled to the transistor MP, and a second terminal coupled to the electrical load 40. The detection resistor RDET can be optionally coupled to the ADC 420, wherein the detection resistor RDET is coupled to the ADC 420 during power control of the VDAC and the transistor MP; and the detection resistor RDET is disconnected from the ADC 420 when the power control of the VDAC and the transistor MP is not performed.

The ADC 420 converts the detection current through the detection resistor RDET into a digital signal and sends it to the digital control unit 10, which generates the digital code D for the digital-to-analog converter 30 based on the digital signal D, to control the digital-to-analog converter 30 for generating the DAC output voltage VD. In FIG. 4, the transistor current flowing through the automatic power control circuit 50E can be used to control the digital-to-analog converter 30 to generate the DAC output voltage VD.

The detection current i of the detection resistor RDET can be expressed as: i=(V1−V2)/RDET, wherein V1 and V2 are the voltages across the two terminals of the detection resistor RDET detected by the ADC 420. The detection current i of the detection resistor RDET is substantially very close to the current flowing through the transistor MP.

In a similar manner, the power consumption P of the transistor M1 is P=(VSUPPLY−VOUT)*i. Therefore, when the digital control unit 10 determines that P exceeds the allowable power limit (or, to be higher than the upper limit of the allowable power limit), the digital control unit 10 adjusts the DAC output voltage VD generated by the digital-to-analog converter 30 to a lower value, to reduce the power consumption P until P falls within the allowable power limit (or, less than the upper limit of the allowable power limit). Naturally, this control must still satisfy the condition (VSUPPLY−VOUT)≥VDS_MIN.

While the above embodiments are illustrated with a VDAC, it is understood that the present invention can also be applicable for other types of DACs, such as IDAC (current mode DAC), which remains within the scope of the present invention. In other words, the approach described in the above embodiment can also be used to control the power consumption of an IDAC.

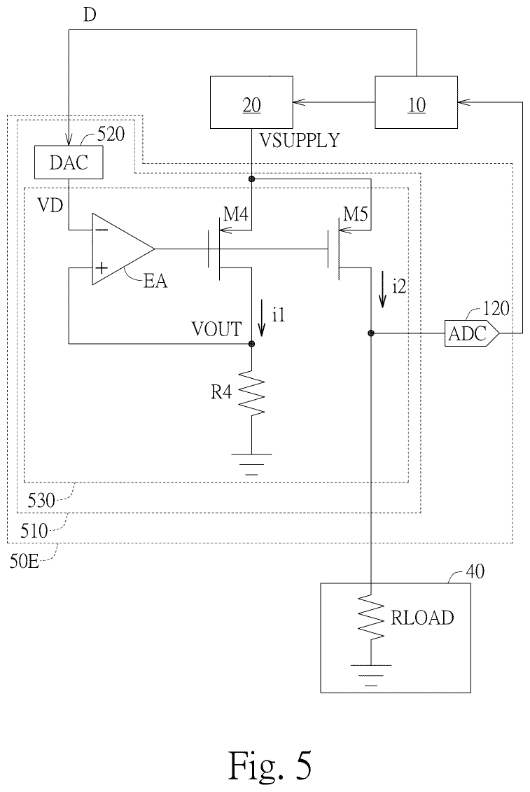

FIG. 5 shows a schematic circuit diagram of the automatic power control circuit according to one embodiment of the present invention. Therein, the automatic power control circuit 50E may be applied to, for example, but not limited to, an optical communication chip. The automatic power control circuit 50E includes a current mode digital-to-analog converter (IDAC) 510 and an ADC 120 (optional component). The current mode digital-to-analog converter (IDAC) 510 includes: a digital-to-analog converter (DAC) 520 and an output buffer circuit 530.

The output buffer circuit 530 includes: transistors M4-M5, the error amplifier EA, and a resistor R4.

The transistor M4 includes: a first terminal (e.g., a source terminal) receiving the supply voltage VSUPPLY generated by the DC-DC converter 20; a second terminal (e.g., a drain terminal) coupled to the resistor R4; and a control terminal (e.g., a gate terminal) receiving an output signal from the error amplifier EA.

The transistor M5 includes: a first terminal (e.g., a source terminal) receiving the supply voltage VSUPPLY generated by the DC-DC converter 20; a second terminal (e.g., a drain terminal) coupled to the ADC 120 and the electrical load 40; and, a control terminal (e.g., a gate terminal) receiving the output signal from the error amplifier EA. Herein, the transistors M4 and M5 form the current mirror circuit.

The error amplifier EA includes: a first terminal (e.g., a positive input terminal) coupled to the resistor R4; a second terminal (e.g., a negative input terminal) receiving the voltage VD generated by the digital-to-analog converter 520; and an output terminal coupled to the control terminals of the transistors M4 and M5.

The resistor R4 is coupled between transistor M4 and grounding, to convert a current (i1) of the fourth transistor M4 into the internal node voltage VOUT.

The ratio of the transistor M4 to the transistor M5 can be, for example, m:n. The ratio of the current i1 flowing through transistor M4 to the current i2 flowing through transistor M5 is: i1:i2=m:n, wherein i1=VD/R4. The analog-to-digital converter 120 converts the current i2 flowing through transistor M5 into a digital signal and sends the digital signal to the digital control unit 10, to allow the digital control unit 10 to generate the digital code D based on the digital signal. The digital code D is sent to digital-to-analog converter 520.

Since the operating details of the automatic power control circuit 50E are fundamentally similar to those of the automatic power control circuit 50A, its details are not elaborated here.

From the above, in the embodiments of the present invention, the automatic power control circuit enables the control of power consumption reduction in the internal transistors and the VDAC/IDAC.

The details of the specification should not be construed as limitations on the scope of the present invention claimed, but rather as illustrative descriptions of the embodiments. In the specification, feature(s) in any embodiment can also be implemented in various combinations with some features of the embodiment or other embodiments. In the drawings, the operations are depicted as being performed in a specific order; however, these should not be understood that these operation steps must be performed in the exact order or sequence as shown in drawing(s), nor that all operation steps must be fully executed to achieve the desired result.

The above embodiments of the present invention disclose only some examples and method implementation. Based on what is disclosed, modifications and enhancements may be made to the examples and implementations described above and to other implementations.

The present invention has been disclosed with reference to the above embodiments, which are not intended to limit the spirit and scope of the present invention. A person skilled in the art to which the present disclosure pertains may make various modifications and adjustments without departing from the spirit and scope of the present disclosure. Accordingly, the scope of protection of the present invention can be defined by the claims.

What is claimed is:

1. An automatic power control circuit for optical communication chip, coupled to a digital control unit and a DC-DC converter, the automatic power control circuit including:
a digital-to-analog converter (DAC), coupled to the digital control unit, the digital-to-analog converter receiving a digital code from the digital control unit, and correspondingly generating a DAC output voltage of the digital analog converter;
an output buffer circuit, coupled to the digital-to-analog converter and the DC-DC converter, the output buffer circuit providing an internal node voltage; and
an analog digital converter, coupled to the output buffer circuit and the digital control unit, the analog-to-digital converter controlling a supply voltage from the DC-DC converter through the digital analog converter, to maintain a voltage difference between the supply voltage and the internal node voltage to be within a normal operating range.

2. The automatic power control circuit according to claim 1, wherein the analog-to-digital converter adjusts the supply voltage, for reducing the supply voltage to be closer to the internal node voltage, wherein a lower voltage difference between the supply voltage and the internal node voltage, makes a lower power consumption of the automatic power control circuit.

3. The automatic power control circuit according to claim 1, wherein the analog-to-digital converter detects the internal node voltage of the output buffer circuit, and converts the internal node voltage into a digital signal, and the digital control unit generates the digital code according to the digital signal.

4. The automatic power control circuit according to claim 1, wherein the output buffer circuit includes:
a first transistor, including a first terminal to receive the supply voltage from the DC-DC converter, a second terminal coupled to an electrical load, and a control terminal;
a first error amplifier, including a first terminal, a second terminal to receive the DAC output voltage generated by the digital analog converter, and an output terminal coupled to the control terminal of the first transistor; and
a voltage divider circuit, dividing the voltage at an internal node to obtain a divided voltage, which is coupled to the first terminal of the first error amplifier.

5. The automatic power control circuit according to claim 1, wherein the output buffer circuit includes a plurality of output buffer circuits, and the automatic power control circuit further includes a multiplexer coupled between the analog-to-digital converters and the output buffer circuits, wherein the multiplexer selects one of the internal node voltages of the multiple output buffer circuits, to be transmitted to the analog digital converter.

6. The automatic power control circuit according to claim 1, further including: a current mirror circuit, coupled to the output buffer circuit, to mirror an internal transistor current generated by the output buffer circuit.

7. The automatic power control circuit according to claim 6, wherein
the current mirror circuit includes a second transistor, a third transistor, and a detection resistor, wherein
the second transistor includes: a first terminal coupled to the DC-DC converter to receive the supply voltage, a second terminal coupled to the third transistor, and a control terminal coupled to the output buffer circuit;
the third transistor includes: a first terminal, coupled to the second terminal of the second transistor, a second terminal coupled to the detection resistor and the analog digital converter, and a control terminal, coupled to the output buffer circuit; and
the detection resistor includes: a first terminal coupled to the third transistor and the analog digital converter, and a second terminal coupled to grounding;
wherein the analog-to-digital converter converts a detection voltage of the detection resistor into a digital signal, for transmitting the digital signal to the digital control unit.

8. The automatic power control circuit according to claim 1, further including:
current mirror circuit, coupled to the output buffer circuit, to mirror an internal transistor current generated by the output buffer circuit; and
a second error amplifier, coupled to the output buffer circuit and the current mirror circuit, to compare the internal node voltage of the output buffer circuit with a coupled node voltage of the current mirror circuit.

9. The automatic power control circuit according to claim 8, wherein the current mirror circuit includes: a second transistor and a third transistor, and, a detection resistance;
the second transistor, including a first terminal coupled to the DC-DC converter to receive the supply voltage, a second terminal coupled to the third transistor, and a control terminal coupled to the output buffer circuit;
the third transistor, including a first terminal coupled to the second terminal of the second transistor; a second terminal coupled to the detection resistor and an analog digital converter; and a control terminal, receiving an output signal from the second transistor;
the detection resistor, including a first terminal coupled to the third transistor and the analog digital converter, and a second terminal coupled to grounding; and
the second error amplifier, including a first terminal coupled to the internal node voltage, a second terminal coupled to a coupled node of the second transistor and the third transistor of the current mirror circuit, and an output terminal coupled to the control terminal of the third transistor;
wherein, the analog-to-digital converter converts a detection voltage of the detection resistor into the digital signal, for transmitting the digital signal to the digital control unit.

10. The automatic power control circuit according to claim 4, wherein the output buffer circuit further includes:
a detection resistor coupled between the first transistor and the voltage divider circuit, wherein the detection resistor includes a first terminal coupled to the first transistor, and a second terminal coupled to the electrical load; and the detection resistor is selectively coupled to the analog digital converter, wherein during controlling the power consumption of the digital-to-analog converter and the first transistor, the detection resistor is coupled to the analog digital converter;
the analog-to-digital converter converting a detection current of the detection resistor into a digital signal, for transmitting the digital signal to the digital control unit.

11. The automatic power control circuit according to claim 1, wherein the electrical load is a silicon photonic circuit.

12. The automatic power control circuit according to claim 1, wherein the output buffer circuit includes:
a fourth transistor, including a first terminal receiving the supply voltage from the DC-DC converter, a second terminal coupled to a fourth resistor, and a control terminal;
a fifth transistor, including a first terminal receiving the supply voltage from the DC-DC converter, a second terminal coupled to the analog digital converter, and a control terminal, wherein the fourth and fifth transistors form a current mirror circuit;
a first error amplifier, including a first terminal, a second terminal receiving the DAC output voltage from the digital analog converter, and an output terminal coupled to the control terminals of the fourth transistor and the fifth transistor; and
a fourth resistor, coupled to the fourth transistor and the first error amplifier, to convert a current from the fourth transistor into the internal node voltage.
